(19) United States
(12) Patent Application Publication
(10) Pub. No.: US 2026/0164850 A1
(43) Pub. Date: Jun. 11, 2026

(54) METHOD FOR PRODUCING A PLURALITY OF OPTOELECTRONIC SEMICONDUCTOR CHIPS

(71) Applicant: ams-OSRAM International GmbH, Regensburg (DE)

(72) Inventor: Wolfgang Schmid, Gundelshausen (DE)

(21) Appl. No.: 18/706,654

(22) PCT Filed: Sep. 29, 2022
(86) PCT No.: PCT/EP2022/077166

§ 371 Date: May 1, 2024

(30) Foreign Application Priority Data
Nov. 3, 2021 (DE) 10 2021 128 546.1

(51) Int. Cl. H10H 20/01; H10F 71/00

(52) U.S. Cl. CPC H10H 20/013; H10F 71/1272

(57) ABSTRACT

In an embodiment a method for producing a plurality of optoelectronic semiconductor chips includes providing a growth substrate, epitaxially growing a sacrificial layer over the growth substrate, wherein the sacrificial layer comprises InAlP, epitaxially growing an epitaxial semiconductor layer sequence on the sacrificial layer, wherein the epitaxial semiconductor layer sequence comprises an active layer for generating electromagnetic radiation and a contact layer directly adjoining the sacrificial layer, wherein the contact layer comprises InGaAlP, applying a carrier over or on the epitaxial semiconductor layer sequence and wet-chemically etching the sacrificial layer using an etchant, which etches a material of the sacrificial layer selectively over a material of the contact layer.

### CROSS-REFERENCE TO RELATED APPLICATIONS

This patent application is a national phase filing under section 371 of PCT/EP2022/077166, filed Sep. 29, 2022, which claims the priority of German patent application 10 2021 128 546.1, filed Nov. 3, 2021, each of which is incorporated herein by reference in its entirety.

### TECHNICAL FIELD

A method for producing a plurality of optoelectronic semiconductor chips is specified.

### SUMMARY

Embodiments provide an improved method for producing a plurality of optoelectronic semiconductor chips. In particular, embodiments provide a method for producing a plurality of optoelectronic semiconductor chips in which a growth substrate is removed in a simplified manner.

In accordance with one embodiment of the method, a growth substrate is provided. The growth substrate is present in the form of a wafer, for example. In other words, a main surface of the growth substrate has a significantly larger extent than a thickness of the growth substrate. By way of example, the wafer comprises a diameter of at least 6 inches, at least 8 inches or at least 12 inches. Furthermore, the growth substrate is configured for the epitaxial growth of an epitaxial semiconductor layer sequence. For this purpose, the growth substrate comprises in particular a lattice constant the same as or similar to that of the material of the epitaxial semiconductor layer sequence to be grown.

In accordance with a further embodiment of the method, a sacrificial layer is epitaxially grown over the growth substrate. Here and hereinafter, the term “over” means in particular that the elements structurally related to one another by this term need not necessarily be in direct contact with one another, rather that further elements may be arranged therebetween.

Preferably, in the present method, firstly a wafer stack comprising at least the growth substrate and the epitaxial semiconductor layer sequence is produced. The wafer stack may also comprise further layers and elements, such as a carrier and a solder. In particular, the growth substrate is present in the wafer stack as a wafer to which the epitaxial semiconductor layer sequence is applied over the whole area. The further elements, too, such as the carrier and the solder, are preferably arranged over the whole area over the growth substrate. The wafer stack is singulated to form a plurality of optoelectronic semiconductor chips in one of the last method steps.

In order to produce the wafer stack, the growth substrate is present in particular in the form of a wafer. Proceeding from the growth substrate, a wafer stack is produced by whole-area epitaxial growth of the epitaxial semiconductor layer sequence, the sacrificial layer and optionally further layers. The carrier is likewise applied over the whole area over or on the epitaxial semiconductor layer sequence. The wafer stack thus produced is singulated so that a plurality of optoelectronic semiconductor chips of identical type arise. In this regard, in particular, a plurality of optoelectronic semiconductor chips are produced simultaneously.

In accordance with a further embodiment of the method, an epitaxial semiconductor layer sequence comprising an active layer, which generates electromagnetic radiation during operation, is epitaxially grown on the sacrificial layer. In this case, a contact layer of the epitaxial semiconductor layer sequence directly adjoins the sacrificial layer. In other words, the contact layer of the epitaxial semiconductor layer sequence and the sacrificial layer form a common interface.

In particular, the contact layer of the epitaxial semiconductor layer sequence in the finished optoelectronic semiconductor chip is configured to electrically contact the active layer and impress a current into the epitaxial semiconductor layer sequence during operation. For this purpose, the contact layer generally comprises a comparatively high doping. In particular, it is possible for the contact layer not to be in direct contact with the active layer and for the active layer to be electrically contacted indirectly via the contact layer.

In accordance with a further embodiment of the method, a carrier is applied over or on the epitaxial semiconductor layer sequence. The carrier is configured in particular to mechanically stabilize the epitaxial semiconductor layer sequence. In particular, the carrier is applied over the whole area over or on the epitaxial semiconductor layer sequence.

In accordance with a further embodiment of the method, the sacrificial layer is wet-chemically etched using an etchant which etches the material of the sacrificial layer selectively over the material of the contact layer. In other words, the etchant etches the material of the sacrificial layer with a higher etching rate than the material of the contact layer. By way of example, an etching rate of the etchant for the material of the sacrificial layer is at least ten times as high, at least thirty times as high or at least fifty times as high as an etching rate of the etchant for the material of the contact layer. In particular, the sacrificial layer is part of the wafer stack during etching.

In particular, a method for producing a plurality of optoelectronic semiconductor chips comprises the following steps:
providing a growth substrate,
epitaxially growing a sacrificial layer over the growth substrate,
epitaxially growing an epitaxial semiconductor layer sequence comprising an active layer, which generates electromagnetic radiation during operation, on the sacrificial layer, a contact layer of the epitaxial semiconductor layer sequence directly adjoining the sacrificial layer,
applying a carrier over or on the epitaxial semiconductor layer sequence,
wet-chemically etching the sacrificial layer using an etchant which etches the material of the sacrificial layer selectively over the material of the contact layer.

Preferably, the steps are carried out in the order specified above. Preferably, at least some of the specified steps produce a wafer stack.

In accordance with a further embodiment of the method, the epitaxial semiconductor layer sequence comprises a phosphide compound semiconductor material. Phosphide compound semiconductor materials are compound semiconductor materials which contain phosphorus, such as the materials from the system InₓAl_{y}Ga_{1-x-y}P where 0≤x≤1, 0≤y≤1 and x+y≤1.

In accordance with a further embodiment of the method, the sacrificial layer comprises InAlP or consists of InAlP, while the contact layer comprises InGaAlP or consists of InGaAlP. InAlP denotes in particular a phosphide compound semiconductor material in accordance with the formula above in which 1-x-y=0 holds true and which therefore does not comprise a portion of gallium. InGaAlP denotes in particular a phosphide compound semiconductor material in accordance with the formula above in which x>0, y>0 and 1-x-y>0 hold true. In other words, InGaAlP also comprises gallium besides indium and aluminum.

By way of example, the sacrificial layer has a thickness of between 100 nanometers and 1 micrometer inclusive or between 100 nanometers and 500 nanometers inclusive or between 100 nanometers and 300 nanometers inclusive.

By way of example, the contact layer has a thickness of between 20 nanometers and 200 nanometers inclusive or between 75 nanometers and 150 nanometers inclusive.

In accordance with a further embodiment of the method, the etchant comprises HCl (hydrochloric acid) or consists of HCl, in particular dilute HCl. Finally, further materials are also suitable for the etchant.

In accordance with a further embodiment of the method, the carrier comprises one of the following materials or consists of one of the following materials: Si, SiN.

In particular, the etchant is suitable for etching InAlP selectively over InGaAlP. In other words, the etchant has a higher etching rate for InGaAlP than for InAlP. By way of example, HCl etches InAlP selectively over InGaAlP.

In accordance with a further embodiment of the method, the growth substrate comprises GaAs. Furthermore, it is also possible for the growth substrate to consist of GaAs.

In accordance with a further embodiment of the method, a buffer layer comprising AlGaAs is arranged between the sacrificial layer and the growth substrate. By way of example, the buffer layer is epitaxially grown.

By way of example, the buffer layer comprises AlGaAs comprising a molar proportion of 80% Al. AlGaAs is in particular an arsenide compound semiconductor material. Arsenide compound semiconductor materials are compound semiconductor materials which contain arsenic, such as the materials from the system InₓAl_{y}Ga_{1-x-y}As where 0≤x≤1, 0≤y≤1 and x+y≤1. AlGaAs fulfils this formula where x=0. In other words, AlGaAs does not comprise indium.

In accordance with a further embodiment of the method, the buffer layer is partly or preferably completely removed before etching of the sacrificial layer by wet-chemical etching. The wet-chemical etching of the buffer layer is preferably affected using a different etchant than the wet-chemical etching of the sacrificial layer. In other words, the wet-chemical etching of the buffer layer is affected in a method step which is separate from the etching of the sacrificial layer. However, it is entirely possible for material of the sacrificial layer also to be concomitantly removed during etching of the buffer layer, particularly if the sacrificial layer and the buffer layer form a common interface. Particularly preferably, however, this material removal is affected only partly, with the result that material of the sacrificial layer remains over the whole area on the contact layer. By way of example, a buffer layer comprising AlGaAs or consisting of AlGaAs is etched using HF (hydrofluoric acid).

In accordance with a further embodiment of the method, the growth substrate is partly or preferably wholly removed by wet-chemical etching before etching of the sacrificial layer. Particularly preferably, the wet-chemical etching of the growth substrate is affected not only before etching of the sacrificial layer, but also before etching of the buffer layer, if the latter is present. The wet-chemical etching of the growth substrate is preferably affected using a different etchant than the wet-chemical etching of the sacrificial layer and/or the buffer layer. In other words, the wet-chemical etching of the growth substrate is preferably affected in a method step which is separate from the etching of the sacrificial layer and/or the buffer layer.

Furthermore, it is also possible, however, for in particular the growth substrate and the buffer layer to be wet-chemically removed jointly in one step using the same etchant.

In particular, it is possible for material of the sacrificial layer also to be removed during wet-chemical etching of the growth substrate, particularly if the sacrificial layer and the growth substrate form a common interface. During joint etching of growth substrate and buffer layer, too, material of the sacrificial layer may be removed. Particularly preferably, however, this material removal is affected only partly, with the result that material of the sacrificial layer remains over the whole area on the contact layer.

One concept of the present method is to provide the sacrificial layer in order to compensate for fluctuations during etching of the growth substrate and/or the buffer layer. During etching of the growth substrate and/or the buffer layer, on account of process fluctuations and/or thickness fluctuations of the growth substrate, the material of the underlying layer is generally attacked in places, this layer being the contact layer in a conventional method. This is the case particularly when a plurality of wafer stacks are etched simultaneously. Conventional methods attempt to compensate for this disadvantageous effect by means of a high thickness of the contact layer. However, a greater thickness of the contact layer has the disadvantage of an increased absorption of electromagnetic radiation in the finished optoelectronic semiconductor chip and a poorer crystal quality of the epitaxial layers subsequently grown epitaxially. With the aid of the sacrificial layer, it is possible to prevent the contact layer from being etched in places.

In accordance with a further embodiment of the method, the carrier is applied over or on the epitaxial semiconductor layer sequence by soldering. Furthermore, the carrier may also be applied over or on the epitaxial semiconductor layer sequence by adhesive bonding or by a connecting method free of joining material.

In accordance with one embodiment of the method, a plurality of wafer stacks comprising at least the growth substrate and the epitaxial semiconductor layer sequence are produced and etched simultaneously. Both the etching of the growth substrate and the etching of the sacrificial layer may be carried out simultaneously at a plurality of wafer stacks.

In accordance with a further embodiment of the method, a plurality of wafer stacks are etched simultaneously.

In accordance with a further embodiment of the method, the wafer stack comprising the epitaxial semiconductor layer sequence, the carrier and the growth substrate comprises a flexure. Particularly if the material of the growth substrate and the material of the carrier comprise different coefficients of thermal expansion, a flexure of the wafer stack arises during thermal loading, for instance during soldering. In this case, the use of a mechanical method for thinning the growth substrate is preferably dispensed with. A growth substrate as part of a wafer stack comprising a flexure may be uniformly thinned by a mechanical method, such as polishing or grinding, only with difficulty. Therefore, mechanical thinning of the growth substrate is preferably dispensed with in the present method.

Further advantageous embodiments and developments of the method will become apparent from the exemplary embodiment described below in association with the figures.

### BRIEF DESCRIPTION OF THE DRAWINGS

FIGS. 1 to 4 show schematic sectional illustrations of stages of a method in accordance with one exemplary embodiment.

### DETAILED DESCRIPTION OF ILLUSTRATIVE EMBODIMENTS

Identical elements, elements of identical type or identically acting elements are provided with the same reference signs in the figures. The figures and the size relationships of the elements illustrated in the figures among one another should not be regarded as to scale. Rather, individual elements, in particular layer thicknesses, may be illustrated with an exaggerated size in order to enable better illustration and/or in order to afford a better understanding.

In the methods in accordance with the exemplary embodiment in FIGS. 1 to 4, firstly a growth substrate 1 is provided. In the present case, the growth substrate 1 is a GaAs wafer (FIG. 1).

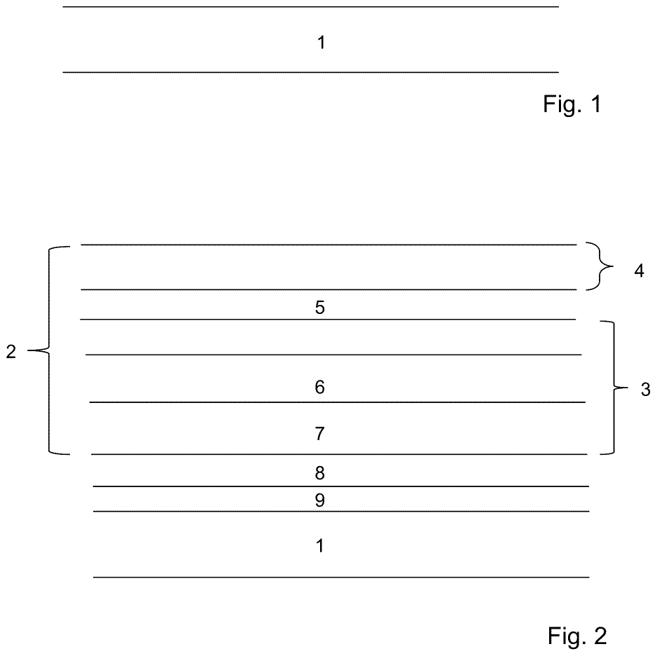

In a next step, an epitaxial semiconductor layer sequence 2 is epitaxially grown on the growth substrate 1 (FIG. 2). In the present case, the epitaxial semiconductor layer sequence 2 is based on a phosphide compound semiconductor material.

The epitaxial semiconductor layer sequence 2 comprises an n-doped region 3 and a p-doped region 4, an active layer 5 being arranged between the n-doped region 3 and the p-doped region 4. In the present case, the active layer 5 is configured to generate electromagnetic radiation during operation.

In the present case, the n-doped region 3 comprises a roughening layer 6 comprising a thickness of approximately 1000 nanometers. In the present case, the roughening layer 6 comprises InAlP. Furthermore, the epitaxial semiconductor layer sequence 2 comprises a contact layer 7. The contact layer 7 comprises InGaAlP and a thickness of approximately 100 nanometers. In the present case, the contact layer 7 is arranged in direct contact with the roughening layer 6.

A sacrificial layer 8 comprising a thickness of approximately 300 nanometers is arranged between the epitaxial semiconductor layer sequence 2 and the growth substrate 1. In the present case, the sacrificial layer 8 is formed from InAlP and grown epitaxially. The sacrificial layer 8 is in direct contact with the contact layer 7 of the epitaxial semiconductor layer sequence 2.

Furthermore, a buffer layer 9 is arranged between the sacrificial layer 8 and the growth substrate 1. The buffer layer 9 is in direct contact both with the sacrificial layer 8 and with the growth substrate 1. In the present case, the buffer layer 9 comprises AlGaAs comprising an aluminum proportion of 80%. The buffer layer 9, too, is grown epitaxially.

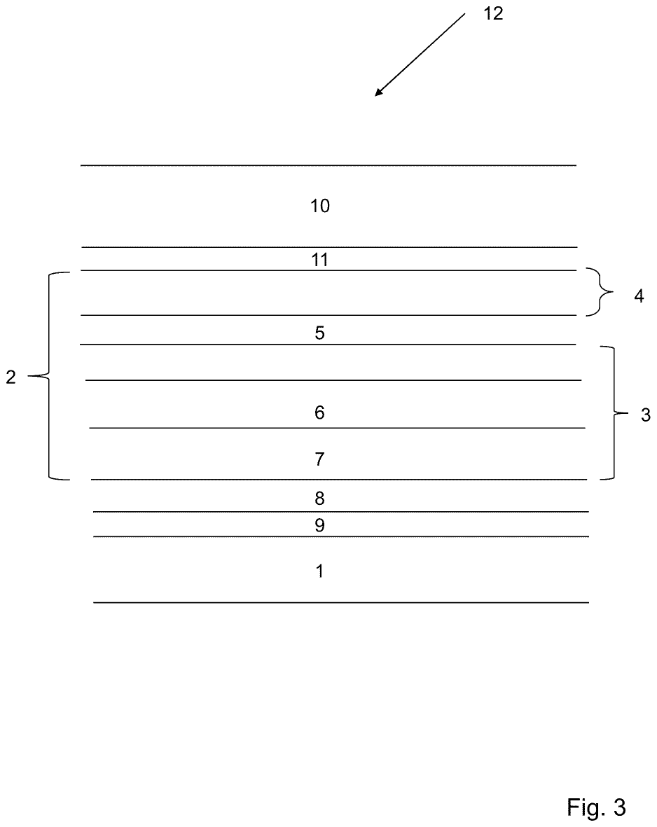

In a next step, a carrier 10 is secured with the aid of a solder 11 in the form of a solder layer on the epitaxial semiconductor layer sequence 2 (FIG. 3). In the present case, the carrier 10 comprises silicon or silicon nitride or is formed from one of these materials.

In a next step, firstly the growth substrate 1 is removed by wet-chemical etching, for example using dilute sulfuric acid with hydrogen peroxide.

In a next step, the buffer layer 9 is then removed wet-chemically using hydrofluoric acid (HF). It is also possible for the buffer layer 9 and the growth substrate 1 to be removed in a common step by wet-chemical etching. Furthermore, the growth substrate 1 can also be etched selectively over the buffer layer 9.

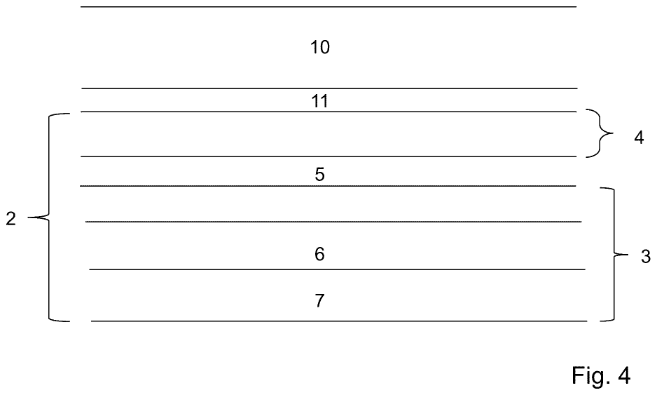

In a further step, the sacrificial layer 8 is etched selectively with respect to the contact layer 7 using hydrochloric acid (HCl) (FIG. 4). In this case, the hydrochloric acid is diluted with water. In this case, the mixture ratio of HCl to H₂O comprises a value of approximately 1:30, for example. An etching rate of the dilute hydrochloric acid for the InAlP of the sacrificial layer 8 comprises a value of approximately 50 nanometers/minute, for example, while the etching rate of the dilute hydrochloric acid for the InGaAlP of the contact layer 7 comprises a value of approximately 2 nanometers/minute.

In a later step, not illustrated in the present case, the wafer stack 12 comprising carrier 10, solder 11 and epitaxial semiconductor layer sequence 2 is singulated to form a plurality of optoelectronic semiconductor chips.

The invention is not restricted to the exemplary embodiments by the description on the basis thereof. Rather, the invention encompasses any novel feature and also any combination of features, which includes in particular any combination of features in the patent claims, even if this feature or this combination itself is not explicitly specified in the patent claims or exemplary embodiments.

1.-11. (canceled)

12. A method for producing a plurality of optoelectronic semiconductor chips, the method comprising:
providing a growth substrate;
epitaxially growing a sacrificial layer over the growth substrate, wherein the sacrificial layer comprises InAlP;
epitaxially growing an epitaxial semiconductor layer sequence on the sacrificial layer, wherein the epitaxial semiconductor layer sequence comprises an active layer for generating electromagnetic radiation and a contact layer directly adjoining the sacrificial layer, wherein the contact layer comprises InGaAlP;
applying a carrier over or on the epitaxial semiconductor layer sequence; and
wet-chemically etching the sacrificial layer using an etchant, which etches a material of the sacrificial layer selectively over a material of the contact layer.

13. The method as claimed in claim 12, wherein the etchant comprises HCl.

14. The method as claimed in claim 12, wherein the carrier comprises one of the following materials: Si or SiN.

15. The method as claimed in claim 12, wherein the growth substrate comprises GaAs.

16. The method as claimed in claim 12, further comprising:
arranging a buffer layer comprising AlGaAs between the sacrificial layer and the growth substrate; and
at least partially removing the buffer layer before etching the sacrificial layer by wet-chemical etching.

17. The method as claimed in claim 12, wherein the growth substrate is wholly or partly removed by wet-chemical etching before etching of the sacrificial layer.

18. The method as claimed in claim 12, wherein the epitaxial semiconductor layer sequence is based on a phosphide compound semiconductor material.

19. The method as claimed in claim 12, wherein the carrier is applied over or on the epitaxial semiconductor layer sequence by soldering.

20. The method as claimed in claim 12,
wherein a plurality of wafer stacks comprising at least the growth substrate and the epitaxial semiconductor layer sequence are produced, and
wherein the plurality of wafer stacks are etched simultaneously.

21. The method as claimed in claim 12, wherein the contact layer has a thickness of between 20 nanometers and 200 nanometers, inclusive.
